(19) United States
(12) Patent Application Publication
(10) Pub. No.: US 2026/0022490 A1
(43) Pub. Date: Jan. 22, 2026

(54) MODULAR DOPING SEED FOR DOPING MELT OF SEMICONDUCTOR MATERIAL

(71) Applicant: GlobalWafers Co., Ltd., Hsinchu (TW)

(72) Inventor: Benjamin Michael Meyer, Defiance, MO (US)

(21) Appl. No.: 19/270,745

(22) Filed: Jul. 16, 2025

Related U.S. Application Data
(60) Provisional application No. 63/673,516, filed on Jul. 19, 2024.

(51) Int. Cl. C30B 15/04; C30B 29/06

(52) U.S. Cl. CPC C30B 15/04; C30B 29/06

(57) ABSTRACT

A modular doping seed for charging dopant to a melt of semiconductor material includes a reusable chuck adapter connectable to a seed chuck, a sacrificial spacer connected to the reusable chuck adapter, and a plurality of doping pods connected in series to one another and depending from the sacrificial spacer, where each pod of the plurality of doping pods defines a dopant chamber for receiving dopant therein.

### CROSS-REFERENCE TO RELATED APPLICATIONS

This application claims the benefit of U.S. Provisional Patent Application No. 63/673,516, filed Jul. 19, 2024, the entire contents of which are incorporated herein by reference.

### FIELD

The field of the disclosure relates to growth processes for single crystals made of semiconductor material and, more particularly, to modular doping seeds used for doping semiconductor or silicon melts during a Czochralski crystal growth process.

### BACKGROUND

Single crystal silicon, which is the starting material for most processes for the fabrication of many electronic components such as semiconductor devices and solar cells, is commonly prepared by batch Czochralski (CZ) or Continuous Czochralski (CCZ) methods. In these methods, a polycrystalline source material, such as polycrystalline silicon (“polysilicon”) in the form of solid feedstock material, is charged to a quartz crucible and melted, a single seed crystal is brought into contact with the molten silicon or melt, and a single crystal silicon ingot is grown by slow extraction.

During ingot growth, dopants can be added to the melt to alter the properties and characteristics of the silicon material. For example, in order to achieve a target resistivity for the final wafer product, the ingot crystal can be doped with elements such as phosphorous, boron, etc. If a reliable method of delivering a precise amount of dopant is not used, the final crystal will typically fall outside of the desired specification range. Known systems for adding dopants to a melt utilize dopant feed tubes or other methods for adding the dopant to the melt, before and/or during the growth process. Some known systems may not adequately control the amount of dopant that is added, which can lead to an undercharge or overcharge of the dopant and, as a result, an ingot that does not have the target properties and characteristics (e.g., resistivity). A need exists for systems and methods that enable controlled addition of dopant to a silicon melt.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect, a modular doping seed for charging dopant to a melt of semiconductor material includes a reusable chuck adapter, a sacrificial spacer, and a plurality of doping pods connected in series to one another and depending from the sacrificial spacer. The reusable chuck adapter extends from a first end to a second end and includes a chuck attachment feature proximate the first end. The sacrificial spacer is connected to the reusable chuck adapter proximate the second end of the reusable chuck adapter. Each pod of the plurality of doping pods includes a body that extends from a first end to a second end and defines a dopant chamber for receiving dopant therein, a first coupler adjacent the first end of the pod body, and a second coupler adjacent the second end of the pod body. The second coupler is complementary to the first coupler such that the first coupler of one pod is connectable to the second coupler of an adjacent pod.

In another aspect, a pulling assembly for an ingot puller includes a seed chuck and a modular doping seed connected to the seed chuck. The modular doping seed includes a reusable chuck adapter, a sacrificial spacer, and a plurality of doping pods connected in series to one another and depending from the sacrificial spacer. The reusable chuck adapter extends from a first end to a second end, and is connected to the seed chuck proximate the first end. The sacrificial spacer is connected to the reusable chuck adapter proximate the second end of the reusable chuck adapter. Each pod of the plurality of doping pods defining a dopant chamber for receiving dopant therein.

In yet another aspect, an ingot pulling apparatus for producing a single crystal ingot of semiconductor material includes a housing defining a growth chamber, a crucible assembly for holding a melt of semiconductor material, where the crucible assembly is disposed within the growth chamber, and a pulling assembly for pulling a crystal ingot from the melt of semiconductor material. The pulling assembly includes a seed chuck and a modular doping seed connected to the seed chuck for charging dopant to the melt of semiconductor material. The modular doping seed includes a reusable chuck adapter connected to the seed chuck, a sacrificial spacer connected to the reusable chuck adapter, and a plurality of doping pods connected in series to one another and depending from the sacrificial spacer. Each pod of the plurality of doping pods defines a dopant chamber for receiving dopant therein.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic cross-section side view of an ingot pulling apparatus or ingot puller for forming a single crystal silicon ingot;

FIG. 2 is a perspective view of an example one-piece dopant or doping seed for charging dopant to the pulling apparatus of FIG. 1.

FIG. 3 is an exploded view of the one-piece doping seed shown in FIG. 2.

FIG. 4 is a perspective view of the one-piece doping seed attached to a seed chuck of the pulling apparatus of FIG. 1.

FIG. 5 is a perspective view of an example modular doping seed for charging dopant to the pulling apparatus of FIG. 1.

FIG. 6 is an exploded view of the modular doping seed shown in FIG. 5.

FIG. 7 is a perspective view of a reusable chuck adapter of the modular doping seed shown in FIG. 5.

FIG. 8 is a cross-sectional view of the modular doping seed shown in FIG. 5.

FIG. 9 is an enlarged cross-sectional view of the area denoted “9” in FIG. 8.

FIG. 10 is a side view of a sacrificial spacer of the modular doping seed shown in FIG. 5.

FIG. 11 is an enlarged cross-sectional view of the area denoted “11” in FIG. 8.

FIGS. 12-14 illustrate the modular doping seed of FIG. 5 being submerged in a melt of semiconductor material, as would be seen by an operator through a view port of the pulling apparatus of FIG. 1 during a doping operation.

FIG. 15 is a perspective view of one of a plurality of doping pods suitable for use with the modular doping seed shown in FIG. 5.

FIG. 16 is a cross-sectional view of another embodiment of a modular doping seed for charging dopant to the pulling apparatus of FIG. 1.

Corresponding reference characters indicate corresponding parts throughout the drawings.

### DETAILED DESCRIPTION

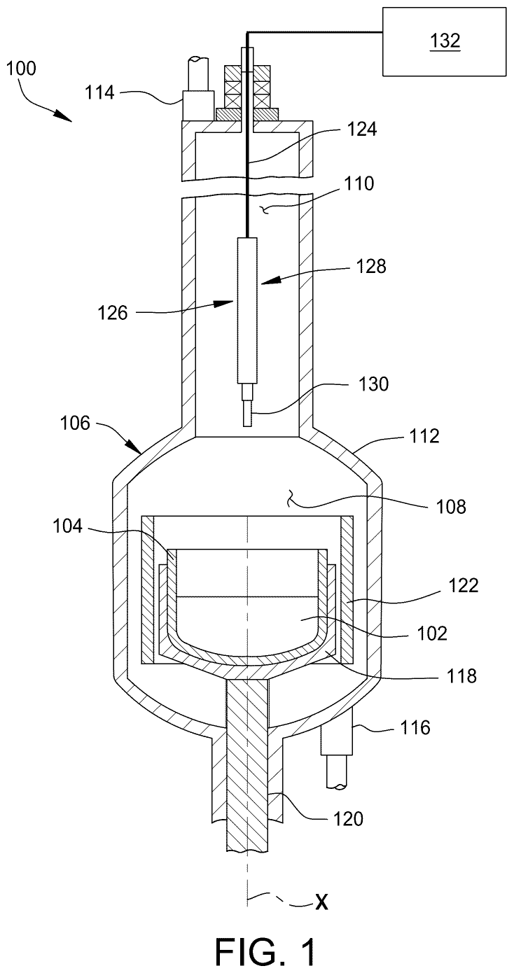

Referring to FIG. 1, an ingot pulling apparatus or ingot puller is shown schematically and is indicated generally at 100. The ingot puller 100 is used to produce single crystal (i.e., monocrystalline) ingots of semiconductor or solar-grade material such as, for example, single crystal silicon ingots. Although the ingot puller 100 is described herein primarily with reference to silicon and single crystal silicon ingots, it is understood that the ingot puller 100 is suitable for use with other types of semiconductor materials, and may be used to produce single crystal semiconductor ingots other than single crystal silicon ingots. In some embodiments, the ingot is grown by the so-called Czochralski (CZ) process in which the ingot is withdrawn from a melt 102 of silicon or other semiconductor material held within a crucible 104 of the crystal puller 100. In some embodiments, the ingot is grown by a batch CZ process in which polycrystalline silicon is charged to the crucible 104 in an amount sufficient to grow one ingot, such that the crucible 104 is essentially depleted of silicon melt 102 after the growth of the one ingot. In other embodiments, the ingot is grown by a continuous CZ (CCZ) process in which polycrystalline silicon is continually or periodically added to crucible 104 to replenish silicon melt 102 during the growth process. The CCZ process facilitates growth of multiple ingots pulled from a single melt 102. Embodiments of the subject matter described herein are not limited to a particular crystal growth process, however.

The ingot puller 100 includes a housing 106 that defines a crystal growth chamber 108 and a pull chamber 110 having a smaller transverse dimension than the growth chamber 108. The growth chamber 108 has a generally dome shaped upper wall 112 transitioning from the growth chamber 108 to the narrowed pull chamber 110. The ingot puller 100 includes an inlet port 114 and an outlet port 116 which may be used to introduce and remove a process gas to and from the ingot puller 100 during crystal growth.

The crucible 104 is positioned within the growth chamber 108 and contains the silicon melt 102 from which a single crystal silicon ingot is drawn. The crucible 104 may be made of quartz or fused silica, which has a high melting point and thermal stability and is generally non-reactive with molten silicon in the melt 102. It should be understood that the crucible 104 may be made from other materials in addition to quartz without departing from the scope of the present disclosure. For example, the quartz crucible 104 may be made from a composite material that includes silica and an additional material, for example, silicon nitride or silicon carbide.

The silicon melt 102 is obtained by melting polycrystalline silicon charged to the crucible 104. In continuous systems, a feed system (not shown) is used for feeding solid feedstock material into the crucible assembly 104 and/or the melt 102. The crucible 104 is positioned within and supported by a susceptor 118 that is in turn supported by a rotatable shaft 120. Susceptor 118 and rotatable shaft 120 facilitate rotation of the crucible 104 about a central longitudinal axis X of the ingot puller 100.

A heating system 122 (e.g., one or more an electrical resistance heaters) surrounds the susceptor 118 and crucible 104 and supplies heat by radiation to the susceptor 118 and crucible 104 for melting the silicon charge to produce the melt 102 and/or maintaining the melt 102 in a molten state. The heater or heating system 122 may also extend below the susceptor 118 and crucible 104 (e.g., with additional, separate heaters). The heating system 122 is controlled by a control system (not shown) so that the temperature of the melt 102 is precisely controlled throughout the pulling process. For example, the controller may control electric current provided to the heating system 122 to control the amount of thermal energy supplied by the heating system 122. The controller may control the heating system 122 so that the temperature of the melt 102 is maintained above the melting temperature of silicon (e.g., about 1412° C.). For example, the melt 102 may be heated to a temperature of at least about 1425° C., at least about 1450° C. or even at least about 1500° C. Insulation (not shown) surrounding the heating system 122 may reduce the amount of heat lost through the housing 106. The ingot puller 100 may also include a heat shield assembly (not shown) above the surface of melt 102 for shielding the ingot from the heat of the crucible 104 to increase the axial temperature gradient at the solid-melt interface.

A pulling mechanism 132 is attached to a pull wire 124 that extends down from the pulling mechanism. The pulling mechanism 132 is capable of raising and lowering the pull wire 124 and rotating the pull wire 124. The ingot puller 100 may have a pull shaft rather than a wire, depending upon the type of puller. The pull wire 124 terminates in a pulling assembly 126 that includes a seed crystal chuck 128 which holds a seed crystal 130 used to grow the silicon ingot. In growing the ingot, the pulling mechanism 132 lowers the seed crystal 130 until it contacts the surface of the silicon melt 102. Once the seed crystal 130 begins to melt, the pulling mechanism 132 slowly raises the seed crystal up through the growth chamber 108 and pull chamber 110 to grow the single crystal ingot. The speed at which the pulling mechanism 132 rotates the seed crystal 130 and the speed at which the pulling mechanism 132 raises the seed crystal (i.e., the pull rate v) are controlled by the ingot puller control system (not shown). As the seed crystal 130 is slowly raised from the melt 102, silicon atoms from the melt 102 align themselves with and attach to the seed crystal 130 to form an ingot.

A process gas (e.g., argon) is introduced through the inlet port 114 into the growth chamber 108 and pull chamber 110 and is withdrawn through the outlet port 116. The process gas creates an atmosphere within the housing. The melt and atmosphere form a melt-gas interface. The outlet port 116 is in fluid communication with an exhaust system (not shown) of the ingot puller.

In at least some ingot growth processes, the melt 102 is charged with a desired amount of dopant prior to and/or during growth of the crystal ingot to achieve a desired or target resistivity for wafers sliced from the resulting ingot. Examples of suitable dopants include, for example and without limitation, phosphorous, boron, arsenic, gallium, antimony, bismuth, and any other elemental dopant suitable for use in CZ doping operations.

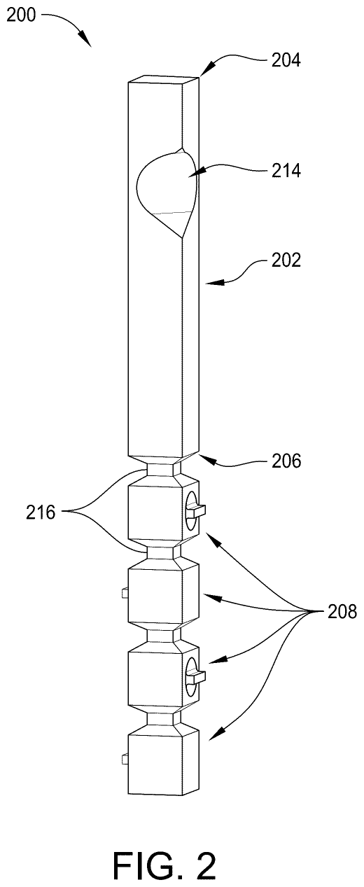

FIG. 2 is a perspective view of an example one-piece dopant or doping seed 200 (or, simply, one-piece “seed”) for charging dopant to a melt of semiconductor material, such as the melt 102 in the ingot puller 100. In this example, the one-piece doping seed 200 includes a main body 202 extending from a first end 204 to a second end 206, and a plurality of doping pods 208 connected in series to one another and depending from the second end 206 of the main body 202. The one-piece doping seed 200 is constructed of a semiconductor material or materials, such as single crystal silicon, and is configured to be consumed, in whole or in part, during a doping operation of the melt 102.

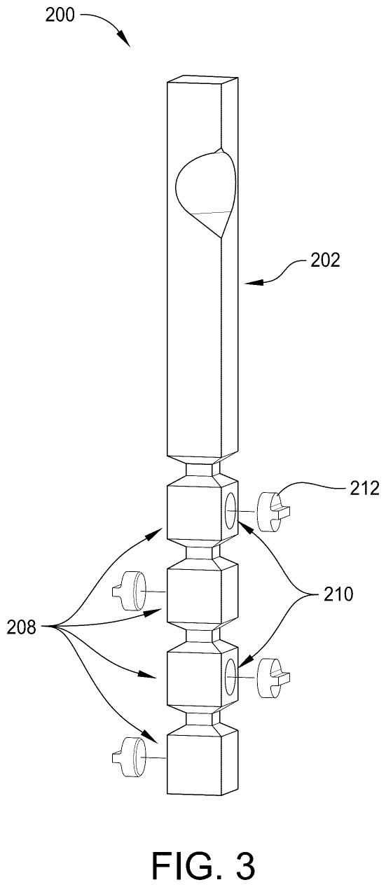

With additional reference to FIG. 3, each doping pod 208 defines a dopant chamber 210 for receiving an amount of dopant therein. Each of the doping pods include a cap 212 that is removably connected to a body of the doping pod 208 to close off the dopant chamber and hold in the dopant. FIG. 3 illustrates the one-piece doping seed 200 with the caps 212 disconnected from the body of each pod 208 to allow dopant to be placed in the dopant chamber 210. In this example, the caps 212 are threadably connected to the pods 208, although the caps 212 could be removably connected to the pods 208 in other ways. After an amount of dopant is added to the dopant chamber 210 of each pod 208, the caps are connected (e.g., screwed on) to the corresponding pod 208 to retain the dopant within the dopant chamber.

As illustrated in FIGS. 2 and 3, the one-piece doping seed 200 includes a chuck attachment feature 214 proximate the first end 204 for connecting the one-piece doping seed 200 to a seed chuck (e.g., seed crystal chuck 128). In this embodiment, the chuck attachment feature 214 comprises a notch defined in the body 202 of the one-piece doping seed 200. The notch is sized and shaped to engage a portion of a seed chuck (e.g., seed crystal chuck 128) to connect the one-piece doping seed 200 to the seed chuck. In this embodiment, the notch is shaped as a spherical segment, although the notch may have any other suitable size and shape that enables the one-piece doping seed 200 to connect to a seed chuck.

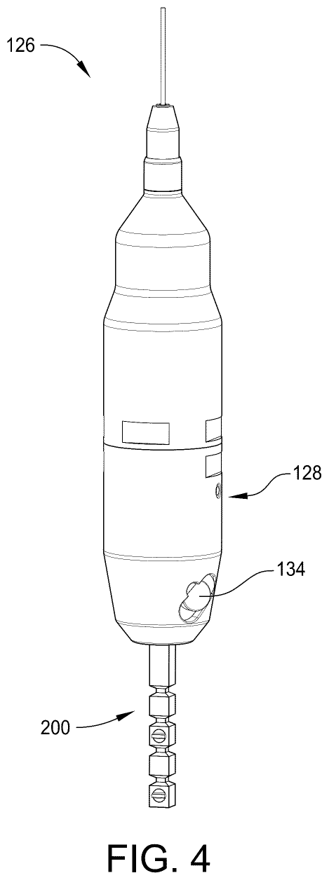

FIG. 4 depicts the one-piece doping seed 200 of FIGS. 2 and 3 attached to the seed crystal chuck 128 of the pulling assembly 126. In the illustrated example, the one-piece doping seed 200 is connected to the chuck 128 by a chuck pin 134 that engages the body 202 of the one-piece doping seed 200 within the notch to inhibit the one-piece doping seed 200 from moving downward.

In operation, the one-piece doping seed 200 is loaded with a desired amount of dopant in each pod 208, and is installed in the ingot puller apparatus 100 (i.e., by connecting the one-piece doping seed 200 to the seed crystal chuck 128). The one-piece doping seed 200 is then lowered towards the melt 102 with the pulling mechanism 132, and the pods 208 are lowered or submerged into the melt 102 and melted (e.g., one at a time) to introduce a desired amount of dopant into the melt 102. After the desired number of pods 208 have been melted, depending on the desired amount of dopant (which may not be all of the pods 208), the remaining portion of the one-piece doping seed 200 is pulled out of the melt 102. The seed chuck 128 is then removed or withdrawn from the growth chamber 108 and a standard seed (e.g., seed crystal 130) is reinstalled into the seed chuck 128 to begin growth of the next crystal ingot.

The full length of the one-piece doping seed 200 need not be used in every doping operation. In some operations, for example, the one-piece doping seed 200 may be removed or separated from the melt 102 prior to all of the doping pods 208 being submerged and melted. To assist an operator of the ingot puller apparatus 100, the one-piece doping seed 200 may include one or more visual indicators 216 to indicate a submersion depth of the one-piece doping seed 200 in the melt 102. In the illustrated example, the one-piece doping seed 200 includes visual indicators 216 in the form of notches—i.e., areas with a reduced cross section or “skinnier” sections—in between the pods 208 to provide a visual indication to the operator when each pod 208 has been fully melted or submerged.

The one-piece doping seed 200 is referred to herein as a “seed”, at least in part, because it is shaped similarly to a standard seed crystal, such as seed crystal 130, used to initiate crystal growth in an ingot puller apparatus (e.g., ingot puller apparatus 100), and attaches to the seed chuck 128 in the same way that a seed crystal 130 does. However, it should be understood that the one-piece doping seed 200 may not be used to initiate or grow single crystal ingots and, at least in some processes, the one-piece doping seed 200 is removed from the seed chuck 128 following a doping operation and replaced with a standard seed crystal, such as seed crystal 130, to initiate crystal growth.

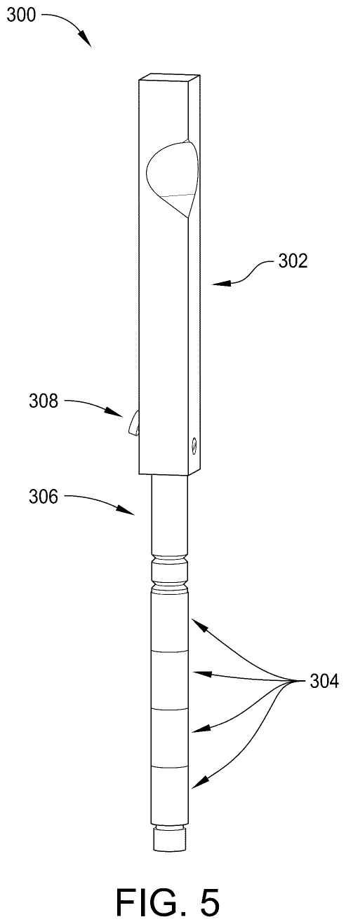

Referring now FIGS. 5-16, in accordance with the present disclosure, one example of a modular doping seed is illustrated generally at 300. The modular doping seed 300 can be used to dope a melt of semiconductor material (e.g., melt 102) instead of the one-piece doping seed 200 shown and described above with reference to FIGS. 2-4. In certain aspects, the modular doping seed 300 provides several advantages as compared to a one-piece doping seed, such as reduced costs, more customized dopant delivery, and reduced chance of dopant delivery error by eliminating the need for an operator to melt only a portion of the pods.

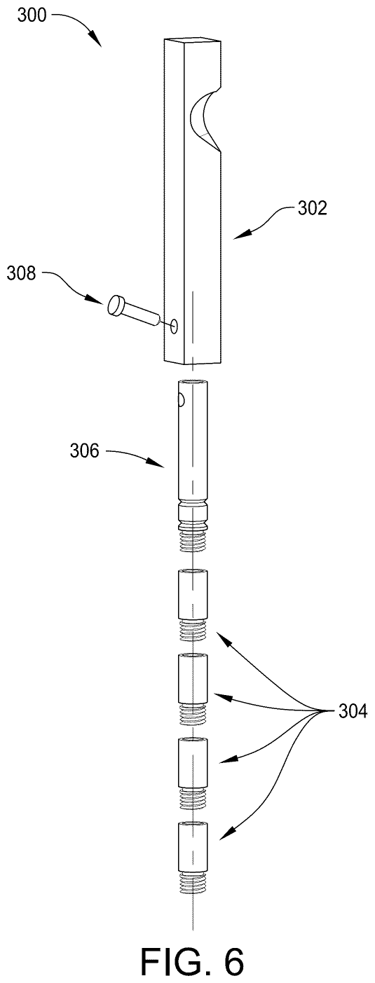

FIG. 5 is a perspective view of the modular doping seed 300 for charging dopant to a melt of semiconductor material, such as the melt 102 in the ingot puller 100. FIG. 6 is an exploded view of the modular doping seed 300. As illustrated in FIGS. 5 and 6, the modular doping seed 300 includes a reusable seed portion or chuck adapter 302 that connects or attaches to a seed chuck (e.g., seed crystal chuck 128), a plurality of modular doping pods 304 for holding an amount of dopant, and a sacrificial spacer 306 that provides a barrier between the doping pods 304 and the reusable chuck adapter 302. The illustrated embodiment also includes a pin 308 to connect the spacer 306 to the reusable chuck adapter 302, although the spacer 306 can be connected to reusable chuck adapter 302 in other ways as described herein.

The modular doping seed 300 functions similarly to the one-piece doping seed 200 to dope a melt of semiconductor material (e.g., melt 102), except portions of the modular doping seed 300 are reusable, thereby reducing costs associated with doping operations, as fewer parts are consumed during each doping operation. Additionally, modular doping seeds of the present disclosure provide more customized dopant delivery, and reduce the chance of dopant delivery error by eliminating the need for an operator to melt only a portion of the pods.

More specifically, the reusable chuck adapter 302 is configured to be removed from the seed crystal chuck 128 after a doping operation, and can be reused in subsequent doping operations. The reusable chuck adapter 302 is suitably constructed of a material or materials capable of withstanding the high temperature environment within the ingot puller 100 while not contaminating the melt or puller environment. Suitable materials from which the reusable chuck adapter 302 can be constructed include, for example and without limitation, graphite, silicon carbide coated graphite, silicon carbide, quartz, and molybdenum. The pin 308 may likewise be configured as a reusable component, and can be constructed of the same materials as the reusable chuck adapter 302 (e.g., graphite, silicon carbide coated graphite, silicon carbide, quartz, and molybdenum).

Other components of the modular doping seed 300, including the doping pods 304 and the sacrificial spacer 306, are designed to be consumed during the doping operation, and can be considered “consumable parts” of the modular doping seed 300. These parts are suitably constructed of a semiconductor material or materials, such as single crystal silicon, and are typically constructed of the same semiconductor material as the melt 102 of semiconductor material in which they are submerged. For example, each pod 304 of the plurality of pods 304 is constructed of semiconductor material. In some embodiments, for example, each pod 304 is constructed of single crystal silicon. In some embodiments, the spacer 306 is also constructed of semiconductor material. In some embodiments, for example, the spacer 306 is constructed of single crystal silicon. In some embodiments, the spacer 306 and each pod 304 of the plurality of pods 304 are constructed of the same material. In other embodiments, the spacer 306 and one or more of the pods 304 can be constructed of different materials. For example, the spacer 306 and/or one or more of the pods 304 could be constructed of one of the dopant materials described herein, provided such dopant material is capable of withstanding (e.g., not deforming or melting) temperatures above the melt 102. In yet other embodiments, one or more of the pods 304 could be constructed of quartz, provided the quartz is sufficiently thin that the quartz pod is capable of melting when submerged in the melt 102.

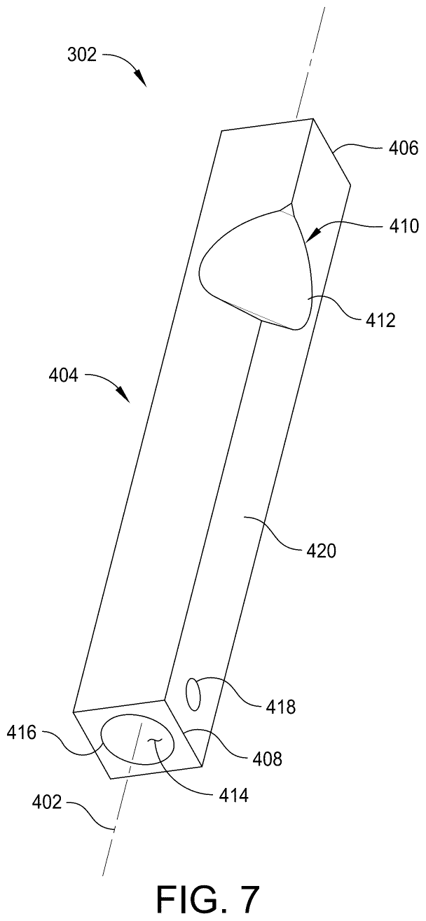

With additional reference to FIG. 7, the reusable chuck adapter 302 defines a longitudinal axis 402, and includes a main body 404 that extends along the longitudinal axis 402 from a first end 406 to a second end 408.

The reusable chuck adapter 302 connects to a seed chuck (e.g., seed crystal chuck 128) proximate the first end 406. In the illustrated embodiment, the reusable chuck adapter 302 includes a chuck attachment feature 410 proximate the first end 406 to enable connection between the modular doping seed 300 and the seed crystal chuck 128 (e.g., via chuck pin 134, as described above with reference to the one-piece doping seed 200). In the illustrated embodiment, the chuck attachment feature 410 comprises a notch 412 defined in the body 404 of the reusable chuck adapter 302. The notch 412 is sized and shaped to engage a portion of a seed chuck (e.g., seed crystal chuck 128) to connect the reusable chuck adapter 302 to the seed chuck. In this embodiment, the notch 412 is shaped as a spherical segment, although the notch 412 may have any other suitable size and shape that enables the reusable chuck adapter 302 to connect to a seed chuck.

The sacrificial spacer 306 is connected to the reusable chuck adapter 302 proximate the second end 408 of the reusable chuck adapter 302. More specifically, the reusable chuck adapter defines a receiving hole 414 at the second end 408 thereof. The receiving hole 414 extends axially from an opening 416 at the second end 408 of the reusable chuck adapter body 404 towards the first end 406. The receiving hole 414 is sized and shaped to receive a portion of the spacer 306 therein. In the illustrated embodiment, the receiving hole 414 has a circular cross section that corresponds to the cylindrical shape of the spacer 306, although the receiving hole 414 may have any other suitable shape that enables the modular doping seed 300 to function as described herein.

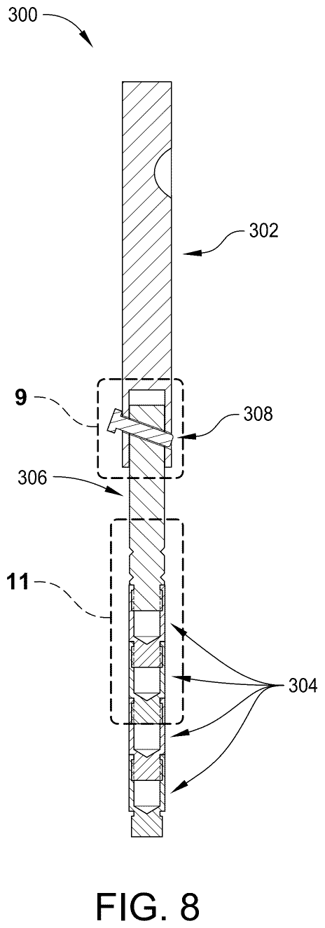

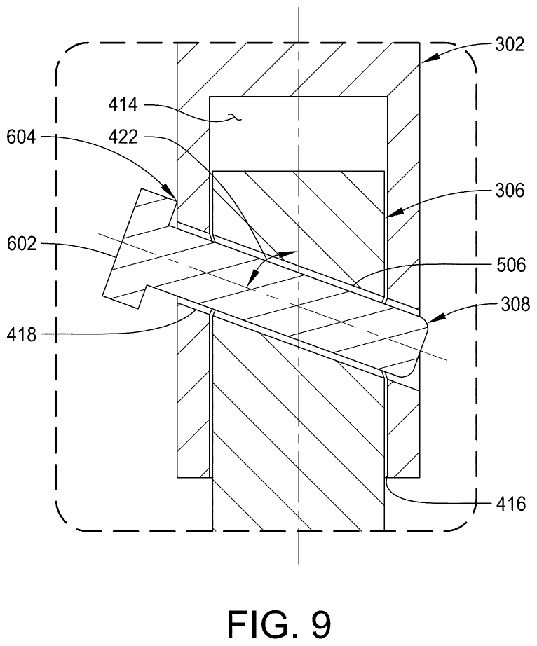

The reusable chuck adapter further defines a through hole 418 extending through a sidewall 420 of the chuck adapter 302 and into communication with the receiving hole 414. In the illustrated embodiment, the through hole 418 extends through the entirety of the chuck adapter body 404, although in other embodiments the through hole 418 may only extend partially through the chuck adapter body 404 into the receiving hole 414. The through hole 418 is sized and shaped to receive the pin 308 therein to connect the spacer 306 to the reusable chuck adapter 302, as illustrated in FIGS. 8 and 9. In the illustrated embodiment, the through hole 418 is oriented at an oblique angle 422 relative to the longitudinal axis 402 of the reusable chuck adapter 302.

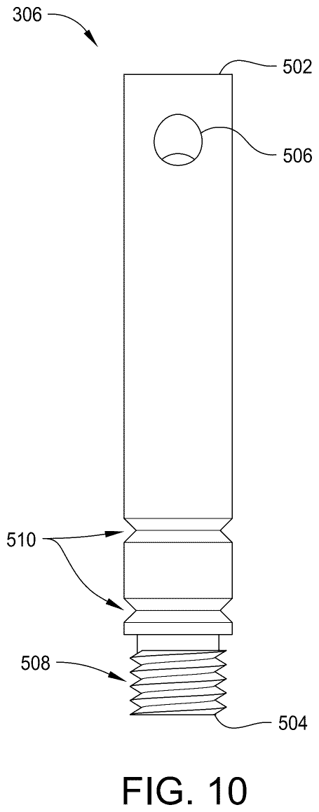

With additional reference to FIG. 10, the spacer 306 extends from a first end 502 to a second end 504, and includes a pin attachment hole 506 proximate the first end 502 of the spacer 306. The pin attachment hole 506 is oriented at the same oblique angle 422 as the through hole 418 such that, when the first end 502 of the spacer 306 is positioned within the receiving hole 414, as shown in FIG. 9, the pin attachment hole 506 aligns with the through hole 418 of the reusable chuck adapter 302. The pin 308 extends through the through hole 418 of the reusable chuck adapter 302 and the pin attachment hole 506 of the spacer 306 to connect to the spacer 306 (specifically, the first end 502 of the spacer 306) to the reusable chuck adapter 302. When the modular doping seed 300 is assembled, the pin 308 is oriented at the same oblique angle 422 as the pin attachment hole 506 and the through hole 418 relative to the longitudinal axis 402 of the reusable chuck adapter 302.

The oblique angle 422 at which the pin 308 is oriented is approximately 20° in the illustrated embodiment, although the oblique angle 422 can be any suitable angle from 0° to 90° that enables the modular doping seed 300 to function as described herein. For example, the oblique angle 422 at which the pin 308 is oriented can be any angle from 0° to 60°, from 30° to 90°, from 10° to 50°, from 30° to 70°, or from 50° to 90°.

Additionally, the pin 308 of the illustrated embodiment includes a head 602 that is designed with a point contact, indicated at 604, to minimize the contact area between the pin 308 and the reusable chuck adapter 302. Minimizing contact area between the pin 308 and the reusable chuck adapter 302 helps prevent the pin 308 from becoming bonded to the reusable chuck adapter 302 during a doping operation. The pin 308 may have other suitable configurations, including a head 602 with rounded edges, chamfered edges, and/or an angled shaped underside to match the profile of the reusable chuck adapter 302.

In other embodiments, the spacer 306 may be connected to the reusable chuck adapter 302 using any suitable connection means that enables the modular doping seed 300 to function as described herein. In some embodiments, for example, the spacer 306 is threadably connected to the reusable chuck adapter 302.

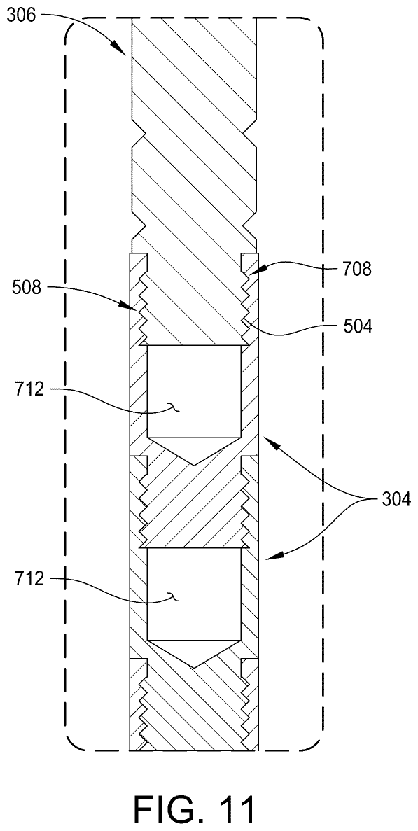

Referring again to FIG. 10, the second end 504 of the spacer 306 is configured as a coupler 508 in the illustrated embodiment to allow one or more of the dopant pods 304 to be connected thereto. The second end 504 of the spacer 306 can include any suitable coupler 508 that enables the spacer 306 to be connected to one or more of the doping pods 304. Suitable couplers include, for example and without limitation, internal threads, external threads, slots or grooves, plugs, pins, or tabs (e.g., for a bayonet style coupler). In some embodiments, for example, the coupler 508 includes external or internal threads such that the pods 304 can be threadably connected to the second end of the spacer 306 (e.g., via complementary threads), as shown in FIG. 11.

The spacer 306 of the example embodiment also includes at least one visual indicator 510 proximate the second end 504 that indicates a submersion depth of the modular doping seed 300 in the melt of semiconductor material. The uniform high temperature in the ingot puller environment can make it difficult to discern or distinguish between different parts of the modular doping seed 300 during operation. The visual indicators 510 create a clear contrast in form of physically distinguishing features that can be more easily discerned by an operator.

In the illustrated embodiment, the spacer 306 includes two visual indicators 510 in the form of annular V-shaped notches or “undercuts” extending around a circumference of the spacer 306. These notches provide a visual indication to an operator of the ingot puller 100 of when the last doping pod 304 (i.e., the doping pod 304 connected to the spacer 306) has been successfully submerged or melted.

In embodiments that include two or more visual indicators 510, each visual indicator 510 can be located at a specific location along the spacer 306 to indicate a condition or state of the doping operation to an operator. In the illustrated embodiment, for example, a first or distal-most visual indicator 510 can be used to indicate when a doping operation has been completed and the modular doping seed 300 can be removed or raised from the melt 102. The second or proximal-most visual indicator 510 can be used to indicate that the modular doping seed 300 has been submerged too deeply or left in too long, and should be immediately withdrawn to avoid damage or excessive wear to the reusable components of the modular doping seed 300 (e.g., the reusable chuck adapter 302).

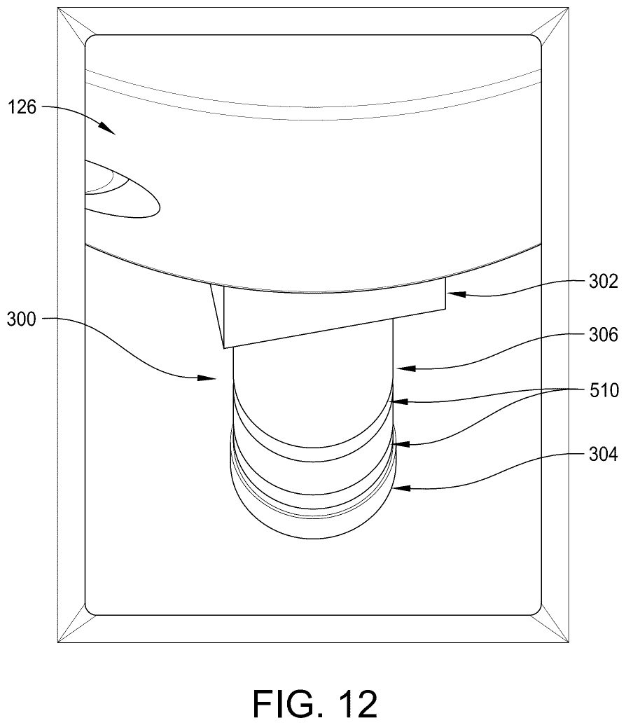

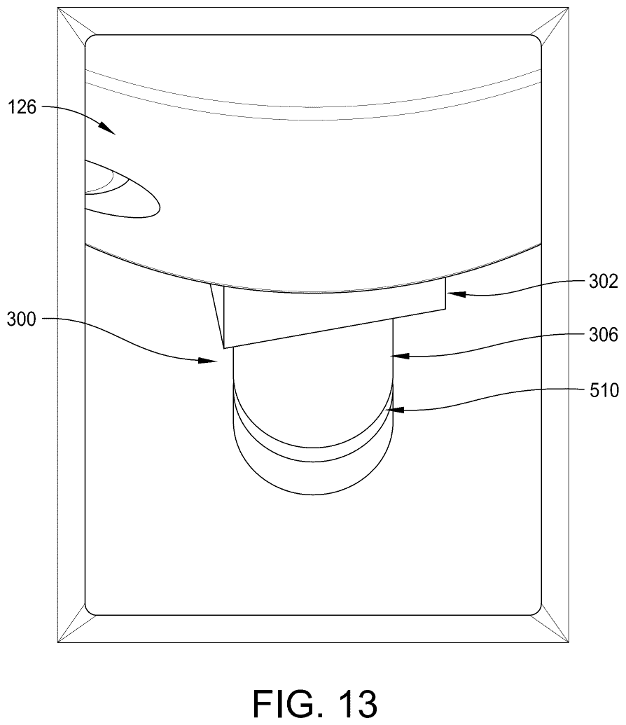

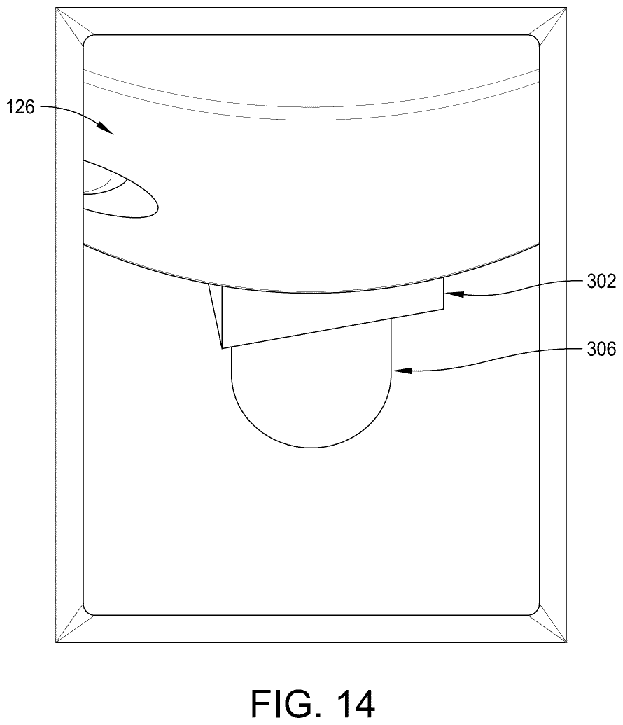

For example, FIGS. 12-14 illustrate the modular doping seed 300 being submerged in the melt 102, as would be seen by an operator through a view port of the ingot puller 100 during a doping operation. FIG. 12 illustrates the modular doping seed 300 when the proximal most doping pod 304—that is, the last doping pod 304 to be submerged or the doping pod 304 connected to the spacer 306—has been nearly submerged and only a small amount of the proximal most doping pod 304 remains above the surface of the melt 102. As shown in FIG. 12, the two visual indicators 510 or notches are still visible on the spacer 306. FIG. 13 illustrates the modular doping seed 300 when one of the visual indicators 510 or notches—specifically, the distal most visual indicator 510—has been submerged or melted away and only a single visual indicator 510 remains. In the illustrated example, when the distal most visual indicator 510 has been submerged or melted, this indicates that the proximal most modular pod 304 has been fully melted, and that the modular doping seed 300 can be raised or pulled out of the melt 102 (e.g., via pulling mechanism 132). FIG. 14 illustrates the modular doping seed 300 when all (i.e., both in this example) of the visual indicators 510 or notches have been melted or submerged. In the illustrated example, when both visual indicators 510 been melted or submerged, this indicates that the modular doping seed 300 has been left in the melt 102 too long and should be immediately withdrawn to avoid damage or excessive wear to reusable components of the modular doping seed 300 (e.g., the reusable chuck adapter 302).

Referring again to FIGS. 5 and 6, the doping pods 304 are connected in series to one another and depend from the sacrificial spacer 306. In the illustrated example, the doping pods 304 are each identical to one another and are configured to be connected to one another and to the second end 504 of the spacer 306, as shown in FIG. 5. Each doping pod 304 includes suitable, complementary connecting means at opposing ends of the pod 304 to allow the pods 304 to connect to one another and to the second end 504 of the spacer 306.

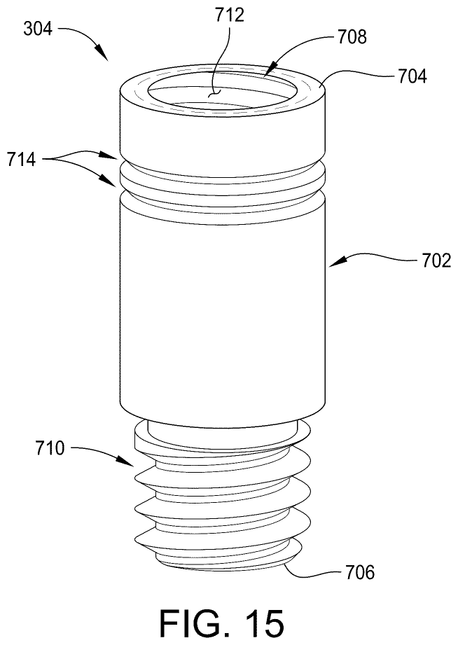

More specifically, and with additional reference to FIG. 15, each doping pod 304 includes a body 702 that extends from a first end 704 to a second end 706, a first type of coupler—or more simply, a first coupler 708—adjacent the first end 704 of the pod body 702, and a second type of coupler—or more simply, a second coupler 710—adjacent the second end 706 of the pod body 702. The second coupler 710 is complementary to the first coupler 708 such that the first coupler 708 of one pod 304 is connectable to the second coupler 710 of an adjacent pod 304. For example, in embodiments where the first coupler 708 includes a male-type coupler (e.g., external threads, plugs, pins, or tabs), the second coupler 710 would include a complementary female-type coupler (e.g., internal threads, external threads, slots or grooves), and vice versa.

In the illustrated example, each pod 304 is threaded at the top—i.e., the first end 704—and the bottom—i.e., the second end 706—so that they may be attached to the spacer 306 as well as daisy chained—i.e., connected to one another end-to-end to form a chain. That is, the first coupler 708 and the second coupler 710 comprise complementary threads in the illustrated example. Specifically, the first coupler 708 includes internal threads and the second coupler 710 includes complementary external threads. In some embodiments, the first coupler 708 includes external threads and the second coupler 710 includes complementary internal threads. In yet other embodiments, the first coupler 708 and the second coupler 710 include complementary couplers other than threads.

The body 702 of each pod 304 also defines a dopant chamber 712 (also shown in FIG. 11) for receiving dopant therein. The dopant chamber 712 can be any suitable size and shape that enables the modular doping seed 300 to function as described herein. Suitable dopants that can be loaded into the doping pods 304 include, for example and without limitation phosphorous, boron, arsenic, gallium, antimony, bismuth, and any other elemental dopant suitable for use in CZ doping operations. Volatile dopants, or dopants that evaporate or otherwise turn into a vapor at temperatures typically seen over the melt 102, can suitably be encapsulated within a non-contaminating material having a high enough melting temperature such that vaporized dopant does not escape when the modular pod 702 is over the melt, but can be melted once the pod 702 is dipped or submerged into the melt 102. Dopants that melt at temperatures typically seen over the melt 102 (e.g., prior to the pod 702 be submerged) would still be retained within the pod 702 due to the orientation of the pod 702. Thus, liquid dopants or dopants that melt at temperatures typically seen over the melt 102 can still be used directly in the pod 702.

In use, an amount of a desired dopant is measured and loaded into the pod 304—specifically, into the dopant chamber 712—which is then connected (i.e., screwed onto in the illustrated example) to either the spacer 306 or the next lowest installed pod.

In the illustrated example, each pod 304 also includes at least one visual indicator 714 that indicates a submersion depth of the pod 304 in the melt 102 of semiconductor material. The pods 304 of the illustrated embodiment each include two visual indicators 714 in the form of annular notches or “cut ins” extending around a circumference of the pod body 702. The visual indicators 714 of the pod 304 can be used, for example, to determine when to cease a doping operation in the middle of the doping operation if it is determined that that not all the pods 304 should be melted. In other embodiments, each pod 304 can include only one visual indicator 714 as a melt progress indicator, or can include no visual indicators.

Although the modular doping seed 300 is illustrated as having four doping pods 304 in the example embodiment, it should be understood that the modular doping seed 300 is readily configurable to include more than or fewer than four doping pods. In some embodiments, for example, the modular doping seed 300 can include one doping pod 304, two doping pods 304, three doping pods 304, four doping pods 304, five doping pods 304, more than five doping pods 304, between 1 and 10 doping pods 304, between 1 and 5 doping pods 304, between 2 and 8 doping pods 304, or any other suitable number of doping pods 304 that enables the modular doping seed 300 to function as described herein.

In the illustrated example, the spacer 306 and doping pods 304 have a generally cylindrical shape, although the spacer 306 and the doping pods 304 can have any other suitable shape that enables the modular doping seed 300 to function as described herein. In some embodiments, for example, the spacer 306 and/or the doping pods 304 can have a square or rectangular cross section (e.g., for ease of manufacturing). In such embodiments, the coupling elements of the spacer 306 and the doping pods 304 can still have a cylindrical or round shape (e.g., where the coupling elements are complementary threads).

Additionally, although the doping pods 304 of the illustrated embodiment are shown as having a common length, doping pods can be made in different lengths, while maintaining a common connection interface, so as to provide different sets of doping pods—for example, a set of doping pods with a first length, a set of doping pods with a second length greater than the first length, a set of doping pods with a third length greater than the second length, and so on. The different length doping pods could be combined in various configurations in the modular doping seed 300 to provide a desired amount of dopant delivery to a melt, while potentially minimizing costs associated with the modular doping pods 304.

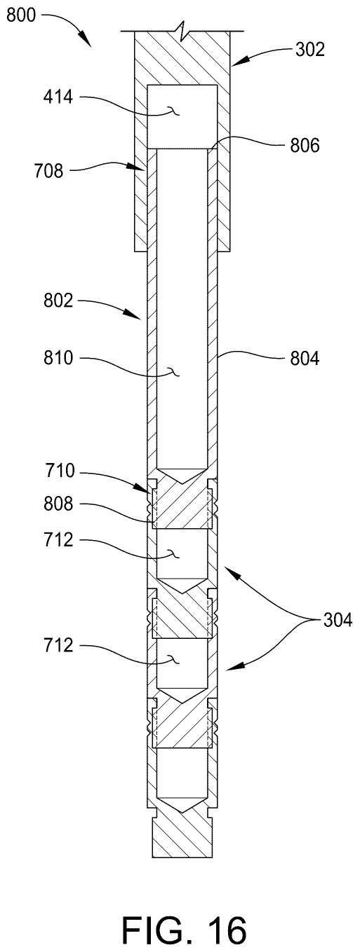

FIG. 16 is a cross-sectional view of another embodiment of a modular doping seed 800 in which the spacer 802 is configured as one of the doping pods. More specifically, the spacer 802 in this embodiment includes a body 804 that extends from a first end 806 to a second end 808 and defines a dopant chamber 810, similar to the doping pods 304. The spacer 802 also includes a first coupler 708 adjacent the first end 806 of the spacer 802 and a second coupler 710 adjacent the second end 808 of the spacer 802 to allow the spacer 802 to connect to the pods 304. In this embodiment, the second end 408 of the reusable chuck adapter 302 also includes a complementary coupler (e.g., threads) to allow the spacer 802 to connect thereto, although the spacer 802 could be connected to the reusable chuck adapter 302 using a pin, as described above. The modular doping seed 800 is otherwise identical to and functions in substantially the same way as the modular doping seed 300, unless otherwise indicated. This design allows one fewer modular piece to be used. Although not shown, the spacer 802 of this example can include visual indicators or melt marks to indicate melt depth, as shown and described with reference to the spacer 306.

Embodiments of modular doping seeds described herein provide several advantages over prior or existing dopant delivery apparatus, including reduced costs, more customized dopant delivery, and reduced chance of dopant amount delivery error. For example, in embodiments of modular doping seeds described herein, the upper seed part or chuck adapter is reused, such that only modular or consumable pieces are sacrificed each time dopant is delivered, rather than the entire seed being lost (since it would no longer has any pods attached to it). Cost and time savings are also realized as compared to one-piece doping seeds, particularly when the amount of dopant needed for a doping operation is greater than the one piece doping seed can deliver in a single run. In such cases, multiple one-piece doping seeds would be required, along with multiple doping operations, requiring a new one-piece doping seed to be attached to the seed chuck each time. In comparison, the modular doping seeds of the present disclosure allow the amount of dopant to be scaled up or down by attaching more or fewer doping pods to the doping seed. The new design thereby reduces time and cost as compared to single piece seed designs by avoiding time associated with switching out single piece seed designs and cost associated with consuming multiple single piece seed designs.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing(s) shall be interpreted as illustrative and not in a limiting sense.

What is claimed is:

1. A modular doping seed for charging dopant to a melt of semiconductor material, the modular doping seed comprising:
a reusable chuck adapter extending from a first end to a second end and comprising a chuck attachment feature proximate the first end;
a sacrificial spacer connected to the reusable chuck adapter proximate the second end of the reusable chuck adapter; and
a plurality of doping pods connected in series to one another and depending from the sacrificial spacer, each pod of the plurality of doping pods comprising:
a body extending from a first end to a second end and defining a dopant chamber for receiving dopant therein;
a first coupler adjacent the first end of the pod body; and
a second coupler adjacent the second end of the pod body, wherein the second coupler is complementary to the first coupler such that the first coupler of one pod is connectable to the second coupler of an adjacent pod.

2. The modular doping seed of claim 1, wherein each pod of the plurality of pods is constructed of semiconductor material.

3. The modular doping seed of claim 2, wherein each pod is constructed of single crystal silicon.

4. The modular doping seed of claim 1, wherein the spacer is constructed of semiconductor material.

5. The modular doping seed of claim 4, wherein the spacer is constructed of single crystal silicon.

6. The modular doping seed of claim 1, wherein the spacer and each pod of the plurality of pods are constructed of the same material.

7. The modular doping seed of claim 1, wherein the reusable chuck adapter defines a receiving hole at the second end thereof, the receiving hole extending from the second end towards the first end of the reusable chuck adapter, wherein a first end of the spacer is received within the receiving hole.

8. The modular doping seed of claim 7, wherein the reusable chuck adapter further defines a through hole extending through a sidewall of the chuck adapter into communication with the receiving hole, wherein the spacer includes a pin attachment hole proximate the first end of the spacer that aligns with the through hole of the reusable chuck adapter when the first end of the spacer is positioned within the receiving hole, and wherein the modular doping seed further comprises a pin that extends through the through hole of the reusable chuck adapter and the pin attachment hole of the spacer to connect to the spacer to the reusable chuck adapter.

9. The modular doping seed of claim 8, wherein the reusable chuck adapter defines a longitudinal axis extending from the first end to the second end, wherein the pin is oriented at an oblique angle relative to the longitudinal axis of the reusable chuck adapter.

10. The modular doping seed of claim 1, wherein the spacer is threadably connected to the reusable chuck adapter.

11. The modular doping seed of claim 1, wherein the spacer extends from a first end to a second end, wherein the first end of the spacer is connected to the reusable chuck adapter, and wherein the spacer includes at least one visual indicator proximate the second end that indicates a submersion depth of the modular doping seed in the melt of semiconductor material.

12. The modular doping seed of claim 11, wherein the at least one visual indicator comprises an annular notch extending around the spacer.

13. The modular doping seed of claim 1, wherein the spacer is configured as one of the doping pods and includes a body defining a dopant chamber for receiving dopant therein.

14. The modular doping seed of claim 1, wherein the reusable chuck adapter is constructed of graphite, silicon carbide coated graphite, silicon carbide, quartz, or molybdenum.

15. The modular doping seed of claim 1, wherein the chuck attachment feature comprises a notch sized and shaped to engage a portion of a seed chuck to connect the reusable chuck adapter to the seed chuck.

16. The modular doping seed of claim 1, wherein the first and second couplers comprise complementary threads.

17. The modular doping seed of claim 1, wherein each pod of the plurality of pods further includes at least one visual indicator that indicates a submersion depth of the pod in the melt of semiconductor material.

18. A pulling assembly for an ingot puller, comprising:
a seed chuck; and
a modular doping seed connected to the seed chuck, the modular doping seed comprising:
a reusable chuck adapter extending from a first end to a second end, wherein the reusable chuck adapter is connected to the seed chuck proximate the first end;
a sacrificial spacer connected to the reusable chuck adapter proximate the second end of the reusable chuck adapter; and
a plurality of doping pods connected in series to one another and depending from the sacrificial spacer, each pod of the plurality of doping pods defining a dopant chamber for receiving dopant therein.

19. The pulling assembly of claim 18, wherein each pod of the plurality of pods is constructed of semiconductor material.

20. The pulling assembly of claim 19, wherein each pod is constructed of single crystal silicon.

21. The pulling assembly of claim 18, wherein the spacer is constructed of semiconductor material.

22. The pulling assembly of claim 21, wherein the spacer is constructed of single crystal silicon.

23. An ingot pulling apparatus for producing a single crystal ingot of semiconductor material, the ingot pulling apparatus comprising:
a housing defining a growth chamber;
a crucible assembly for holding a melt of semiconductor material, the crucible assembly disposed within the growth chamber; and
a pulling assembly for pulling a crystal ingot from the melt of semiconductor material, the pulling assembly comprising:
a seed chuck; and
a modular doping seed connected to the seed chuck for charging dopant to the melt of semiconductor material, wherein the modular doping seed comprises:
a reusable chuck adapter connected to the seed chuck;
a sacrificial spacer connected to the reusable chuck adapter; and
a plurality of doping pods connected in series to one another and depending from the sacrificial spacer, each pod of the plurality of doping pods defining a dopant chamber for receiving dopant therein.
